(19) United States
(12) Patent Application Publication
(10) Pub. No.: US 2008/0111148 A1
(43) Pub. Date: May 15, 2008

(54) Led reflective package

(76) Inventor: Michael A. Zimmerman, North Andover, MA (US)

Correspondence Address: WEINGARTEN, SCHURGIN, GAGNEBIN & LEBOVICI LLP, TEN POST OFFICE SQUARE, BOSTON, MA, 02109, US

(21) Appl. No.: 11/983,791

(22) Filed: Nov. 9, 2007

Related U.S. Application Data
(60) Provisional application No. 60/858,018, filed on Nov. 9, 2006.

(51) Int. Cl. H01L 33/00

(52) U.S. Cl. 257/98; 257/E33.058

(57) ABSTRACT

An LED package which employs a high temperature plastic or polymeric material which is compatible with widely used gold-tin eutectic solder and which can replace the higher cost ceramic used in conventional LED packages. The novel LED package has a high thermal conductivity substrate, a high reflectivity for visible light and/or UV light, and good aging properties. The high temperature material is a high temperature liquid crystal polymer (LCP) having a melting temperature greater than about 340° C. and has small filler particles near the surface, the particles having a refractive index greater than about 2.0, and a size range of about 0.2 to 0.3 microns. For an LED package which is reflective to UV light, a UV stabilizer can be included in the plastic material to improve reflectivity in the ultraviolet spectrum and to protect from UV degradation of the plastic material which can be caused by UV light emitted by some LEDs.

### CROSS REFERENCE TO RELATED APPLICATIONS

This application claims the benefit under 35 U.S.C. § 119(e) of U.S. Provisional Patent Application No. 60/858,018, filed on Nov. 9, 2006, the disclosure of which is incorporated by reference herein.

### STATEMENT REGARDING FEDERALLY SPONSORED RESEARCH OR DEVELOPMENT

N/A

### BACKGROUND OF THE INVENTION

Light emitting diode (LED) devices are made from materials such that light is transmitted either sideways or upwards from the surface of the LED. The LED simultaneously dissipates electrical energy which is converted to heat. The extraction of heat from the LED is important to the performance of the LED. Therefore, a package which provides electrical and optical connections to the LED needs to provide for both thermal and optical efficiency. For a high performance package for these applications, alumina, having a thermal conductivity of 15 W/mK, is often used. For higher thermal performance, aluminum nitride, having a thermal conductivity of 150 W/mK, is used. In both of these cases of alumina and aluminum nitride, the manufacturing process causes the package to be cost inefficient for many applications such as high volume consumer product applications. Also, as LED technology evolves, LED optical power is increasing, which results in the need to dissipate more heat. In addition, optical efficiency has assumed greater importance, suggesting that an LED package should absorb or scatter only small amounts of light. Therefore, a highly reflective LED package is desirable.

The desirable features of an LED package include the following: use of a high thermal conductivity substrate to extract heat (e.g., copper, where thermal conductivity is >300 W/mK), use of high temperature materials which can withstand eutectic die attachment at temperatures near and above 320° C., and use of materials having reflectivities >90% for the package sidewalls. Also, it is desirable to manufacture LED packages employing a low cost manufacturing process such as injection molding.

A known LED package comprises a ceramic base or substrate having a cavity formed in the ceramic base and in which one or more LEDs are mounted. A lens is placed over the cavity and light from the one or more LEDs is emitted through the lens. The cavity has one or more reflective surfaces to enhance the amount of light emitted through the lens. In existing ceramic packages, the reflectivity is provided by an angled cavity wall which is metallized to provide the reflective surface. The ceramic packages are often surface mountable by providing a plurality of surface mount pads on the bottom surface of the ceramic package. The plurality of surface mount pads are mateable to cooperative pads or other contact areas of a circuit board or other mounting structure. The ceramic package provides good thermal conductivity but at a relatively high cost. A typical ceramic package construction in shown in FIGS. 1A and 1B.

Another known LED package includes a base of low temperature plastic material, namely polyphthalamide which is similar to Nylon. Fibrous glass particles and titanium oxide particles are provided in the plastic composition to provide reflectivity. This plastic material has a melting point of 310° C. and a deflection temperature under load (DTUL) of 290° C. (1.82 MPa). In addition, this plastic material has a relatively high moisture absorption of 3.9% and exhibits degradation of reflectivity during aging of the plastic material. A major drawback of this known plastic material is a lack of compatibility with widely-used gold-tin eutectic solder, since this plastic material has a lower melting temperature than the gold-tin eutectic solder used to attach the LED to the base

### BRIEF SUMMARY OF THE INVENTION

The present invention provides an LED package which employs a high temperature plastic or polymeric material which is compatible with widely used gold-tin eutectic solder and which can replace the higher cost ceramic used in conventional LED packages. The novel LED package has a high thermal conductivity substrate, a high reflectivity for visible light and/or UV light, and good aging properties.

The high temperature material is a high temperature liquid crystal polymer (LCP) having a melting temperature greater than about 340° C. The plastic material has small filler particles near the surface, the particles having a refractive index greater than about 2.0, and a size range of about 0.2 to 0.3 microns.

For an LED package which is reflective to UV light, a UV stabilizer can be included in the plastic material to improve reflectivity in the ultraviolet spectrum and to protect from UV degradation of the plastic material which can be caused by UV light emitted by some LEDs.

### BRIEF DESCRIPTION OF THE SEVERAL VIEWS OF THE DRAWINGS

The invention will be more fully described in the following detailed description in conjunction with the drawings in which:

FIG. 1A is a pictorial view of a known LED package;

FIG. 1B is a pictorial view of the bottom side of the LED package of FIG. 1A; and

FIG. 2 is a pictorial view of an LED package fabricated in accordance with the present invention.

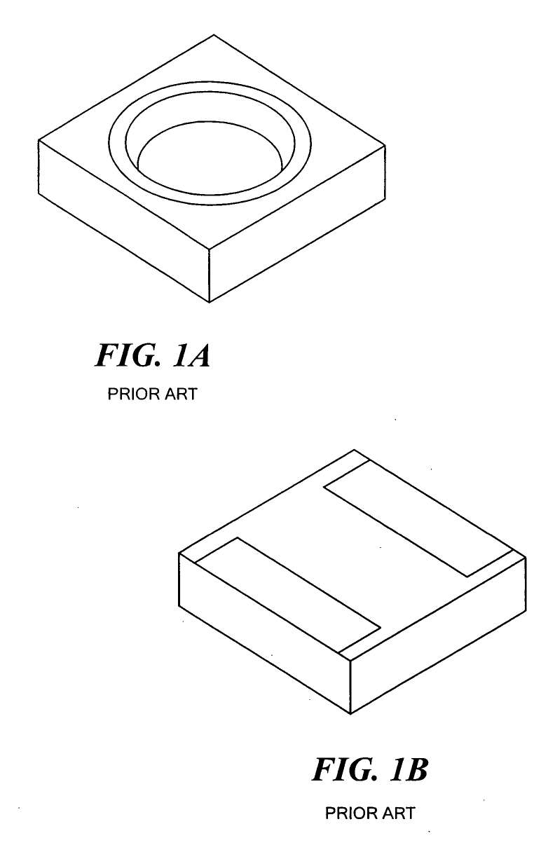

### DETAILED DESCRIPTION OF THE INVENTION

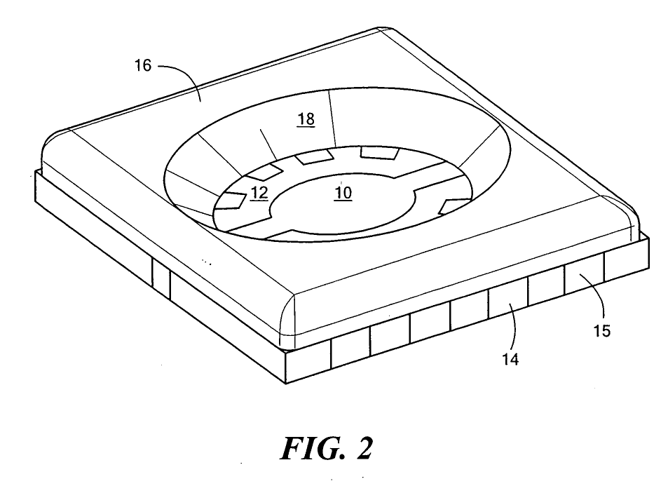

A preferred embodiment of an LED package in accordance with the invention is shown in FIG. 2. The package comprises a substrate 10 having a surface 12 on which one or more LED devices can be mounted and having an opposite surface 14 containing conductive pads 15 for surface mounting of the package to a circuit board or other mounting surface. It will be appreciated that the package can include other known electrical lead configurations to suit particular applications. A housing 16 is disposed on the surface 12 of the substrate and having a cavity surrounding the mounting area for the one or more LEDs. The housing is composed of a high temperature plastic or polymeric material, further described below, and has an angled peripheral surface 18 as shown which acts as a reflective surface for the light emitted by the one or more LEDs. After one or more LEDs are mounted on the surface 14 within the cavity area of the housing, a lens, not shown, is attached over the cavity area to complete the package. The cavity has a mirror finish on at least the angled peripheral surface 18 to reflect emitted light. Preferably, the mirror finish is provided by the mirror finish of the mold used for molding the housing.

The LED package in accordance with the invention comprises high temperature polymeric material having small filler particles at least near the surface, which serve as reflectors for light emitted by the one or more LEDs contained in the LED package. The high temperature material is a high temperature liquid crystal polymer (LCP) having a melting temperature greater than about 340° C. The filler particles have a refractive index greater than about 2.0 and a particle size typically in the range of about 0.2 to 0.3 microns. The filler particles are in the range of about 10-20% by weight of the material composition. The LCP material has a coefficient of thermal expansion in the range of about 5-30 pppm/° C. and preferably in the range of about 10-20 ppm/° C.

Table 1 shows several formulations of the high temperature LCP material for the LED package. The percentages are weight percentages.

TABLE 1

| | #1 | #2 | #3 | #4 | #5 | #6 | #7 |
|---|---|---|---|---|---|---|---|
| Rutile TᵢO₂ | 20% | 20% | 20% | 20% | 20% | 20% | 20% |
| Anatase TᵢO₂ | 10% | 10% | 10% | 10% | 10% | 10% | 10% |
| Polymer | 69.50% | 69.00% | 68.00% | 69.50% | 69.00% | 68.00% | 68.00% |
| ZₙO | 0.50% | 1.00% | 2% | | | | 1.00% |
| nano TᵢO₂ | | | | 0.50% | 1.00% | 2.00% | 1.00% |

The Rutile TᵢO₂ has a particle size range of 0.1-10 microns. The Anatase TᵢO₂ has a particle size range of 0.1-10 microns. The nano TᵢO₂ particles have a size range of 10-100 nanometers.

Alternatively the material composition can contain antimony oxide and calcium carbonate in the range of about 1-10%, and a particle size range of about 0.1-10 microns.

The high temperature polymeric material has a composition which includes one of the following chemical groups: hydroquinine (HQ), 4,4 bisphenol (BP) bis(4-hydroxylphenyl ether) (POP), terephalic acid (TPA), 2,6 naphalene dicarboxylic acid (NPA), 4,4 benzoic acid (BB), 4-hydrosybenzoic acid (HBA), 6-hydroxy-2-naptholic acid (HNA).

Copper or a copper alloy is preferably used as a substrate to provide good electrical and thermal properties. The substrate in one embodiment is a copper alloy containing a minimum of 50% copper. In another embodiment, the substrate has a copper content of greater than 99.0%. The substrate has a thermal conductivity >300 W/mK.

The filler particles are compounded homogenously in the high temperature plastic material during preparation of the material for molding. Preferably, the filler particles are more numerous near the outer surface of the material, and which can be accomplished by known compounding and molding procedures.

LEDs typically operate in the visible light spectrum of 450-700 nm and the package construction described above is useful for this visible light range. There are newer LEDs which operate to emit ultraviolet (UV) light which is then converted to white light, typically by UV stimulation of a phosphor that emits white light. The LED package in accordance with the invention can also be employed for reflecting UV light.

UV light is typically absorbed into organic materials and damages a polymer chain, similar to the phenomenon of UV rays from the sun damaging the human skin. Therefore, it is highly desirable to include ingredients, such as a UV stabilizer, capable of acting as UV scavengers, in the high temperature plastic material, to protect from UV degradation. The UV stabilizer can improve reflectivity in the range of 300-450 nm, and can be of an inorganic material having particle dimensions smaller than about 100 nm. An exemplary inorganic UV stabilizer can be Zinc Oxide or nano TᵢO₂ having a particle size preferably in the range of about 10-50 nm. The inorganic UV stabilizer may typically be included in the high temperature plastic material in an amount of about 0.5-21 by weight.

The invention is not to be limited by what has been particularly shown and described but is to encompass the full spirit and scope of the claims.

What is claimed is:

1. A light emitting diode (LED) package comprising:
a housing of a high temperature plastic material having a top surface, a bottom surface and a cavity, and the cavity sized to accommodate at least one LED;
a substrate attached to the bottom surface of the housing and adapted for attaching at least one LED;
the high temperature plastic material having a melting temperature greater than about 340° C., and a plurality of filler particles; and wherein
the top surface of the housing is adapted to mount a lens.

2. For use in a package containing one or more light emitting diodes mounted on a substrate, a housing having one or more reflective surfaces and comprising:
a body of high temperature polymeric material having a melting temperature greater than about 340° C.;
a cavity configured to surround the one or more light emitting diodes mounted on the substrate;
the cavity having one or more reflective surfaces angled with respect to the substrate by less than about 20° to reflect light from the one or more light emitting diodes; and
the body having a first mounting surface for mounting the body onto the substrate, and having a second mounting surface for attaching a lens through which light from the one or more light emitting diodes can be transmitted.

3. The invention of claim 2 wherein the body of high temperature polymeric material has a composition which includes a chemical group selected from the chemical groups consisting of: hydroquinine (HQ), 4,4 bisphenol (BP) bis(4-hydroxylphenyl ether) (POP), terephalic acid (TPA), 2,6 naphalene dicarboxylic acid (NPA), 4,4 benzoic acid (BB), 4-hydrosybenzoic acid (HBA), 6-hydroxy-2-naptholic acid (HNA).

4. The invention of claim 2 wherein the body of high temperature polymeric material has a filler in the range of 10-60%.

5. The invention of claim 4 wherein the filler includes: TᵢO₂, ZₙO, and glass.

6. The invention of claim 5 wherein TᵢO₂ is present in the range of about 10-22%.

7. The invention of claim 6 wherein ZₙO is <1%.

8. The invention of claim 5 wherein the TᵢO₂ is Rutile TᵢO₂.

9. The invention of claim 5 wherein the TᵢO₂ particles are in the range of 0.1-0.5 microns.

10. The invention of claim 5 wherein the ZₙO particles are <100 nm.

11. The invention of claim 9 wherein the nano TᵢO₂ particles are <100 nm and less than 1% of the filler.

12. The invention of claim 2 wherein the high temperature polymeric material has a coefficient of expansion in the range of about 5 ppm/° C.-30 ppm/° C.

13. The invention of claim 2 wherein the high temperature polymeric material has a coefficient of expansion in the range of about 10-20 ppm/° C.

14. The invention of claim 2 wherein the substrate material has a thermal conductivity which is >300 W/mK.

15. The invention of claim 2 wherein the substrate material is an alloy which contains a minimum of 50% copper.

16. The invention of claim 15 wherein the substrate material has a preferred copper content of >99.0% Cu.
